(19) United States
(12) Patent Application Publication
(10) Pub. No.: US 2015/0263067 A1
(43) Pub. Date: Sep. 17, 2015

(54) SEMICONDUCTOR DEVICE AND METHOD OF MANUFACTURING THE SAME

(71) Applicant: Satoshi INABA, Seongnam-si (KR)

(72) Inventor: Satoshi INABA, Seongnam-si (KR)

(21) Appl. No.: 14/453,316

(22) Filed: Aug. 6, 2014

Related U.S. Application Data
(60) Provisional application No. 61/951,422, filed on Mar. 11, 2014.

(51) Int. Cl. H01L 27/22; H01L 29/36; H01L 29/51; H01L 43/08; H01L 21/02; H01L 21/3065; H01L 43/12; H01L 43/02; H01L 29/423; H01L 29/66

(52) U.S. Cl. CPC H01L 27/228; H01L 29/4236; H01L 29/36; H01L 29/513; H01L 29/66477; H01L 21/02636; H01L 21/3065; H01L 43/12; H01L 43/02; H01L 43/08

(57) ABSTRACT

According to one embodiment, there is provided a semiconductor device, including a semiconductor substrate, a first semiconductor layer formed on a main surface of the semiconductor substrate, the first semiconductor layer containing carbon, a second semiconductor layer formed on the first semiconductor layer, the second semiconductor layer having impurities diffused, a groove part arranged so as to pass through the second semiconductor layer, and a gate electrode embedded in the groove part via a gate insulating film.

### CROSS-REFERENCE TO RELATED APPLICATIONS

This application claims the benefit of U.S. Provisional Application No. 61/951,422, filed Mar. 11, 2014, the entire contents of which are incorporated herein by reference.

### FIELD

Embodiments described herein relate generally to a semiconductor device, a method of manufacturing the same and a nonvolatile semiconductor memory device.

### BACKGROUND

Recently, as a candidate for a large-capacity and high-speed memory device similar to a dynamic memory (DRAM), there has been proposed a resistance-change memory in which electric current is used to change the resistance of elements.

### BRIEF DESCRIPTION OF THE DRAWING

FIG. 1 is a plan view schematically illustrating the structure of a resistance-change memory according to a first embodiment.

FIG. 2 is a sectional view along line I-I′ of FIG. 1 illustrating a memory cell unit.

FIG. 3 is a circuit diagram illustrating the resistance-change memory of FIG. 1.

FIG. 4 is a graph illustrating depthwise impurity concentration distribution on an epitaxial layer.

FIGS. 5A to 5K are cross-sectional views illustrating processes of manufacturing the memory cell unit used for the resistance-change memory of FIG. 1.

FIG. 6 is a cross-sectional view illustrating the structure of a memory cell unit of a resistance-change memory according to a second embodiment.

FIGS. 7A to 7C are cross-sectional views illustrating processes of manufacturing the resistance-change memory according to the second embodiment.

FIG. 8 is a cross-sectional view illustrating a memory cell unit of a resistance-change memory according to a third embodiment.

FIG. 9 is a plan view schematically illustrating the structure of a resistance-change memory according to a fourth embodiment.

FIG. 10 is a pattern view illustrating the height of the substrate surface in the resistance-change memory of FIG. 9.

FIGS. 11A and 11B are cross-sectional views illustrating the effect of the fourth embodiment.

### DETAILED DESCRIPTION

In general, according to one embodiment, there is provided a semiconductor device, comprising a semiconductor substrate, a first semiconductor layer formed on a main surface of the semiconductor substrate, the first semiconductor layer containing carbon, a second semiconductor layer formed on the first semiconductor layer, the second semiconductor layer containing impurities diffused, a groove part arranged so as to pass through the second semiconductor layer, and a gate electrode embedded in the groove part via a gate insulating film.

One example of a resistance-change memory is a 1T/1R type. This type has the important problem as to how a large current is supplied from a transistor to a resistance-change element in a predetermined cell area.

Also, when a MOSFET is used as a cell transistor, the contact area for a source/drain electrode is decreased as the cell area is reduced. It is expected that the increase of a so-called parasitic resistance (contact resistance) greatly affects the deterioration of a current drive. Further, a certain resistor is connected to either of the source or drain electrode of a MOSFET in a 1T/1R type, which can work as a parasitic resistance.

Thus, a 1T/1R-type resistance-change memory conventionally needs to have a transistor capable of supplying sufficient currents bi-directionally in a structure where a parasitic resistance can be small, and a circuit configuration in which the transistor is used. In addition, as for memory characteristic, the characteristic variation of each cell transistor needs to be reduced to the minimum to secure a large operation margin of reading out and writing.

Therefore, in the present embodiments, regarding the cell transistor of the above-mentioned resistance-change memory, there is proposed a device structure where sufficient bi-directional currents can be supplied by decreasing a parasitic resistance and the characteristic variation is small, and a method of manufacturing the same.

Hereinafter, semiconductor devices according to embodiments will be described with reference to the accompanying drawings.

### FIRST EMBODIMENT

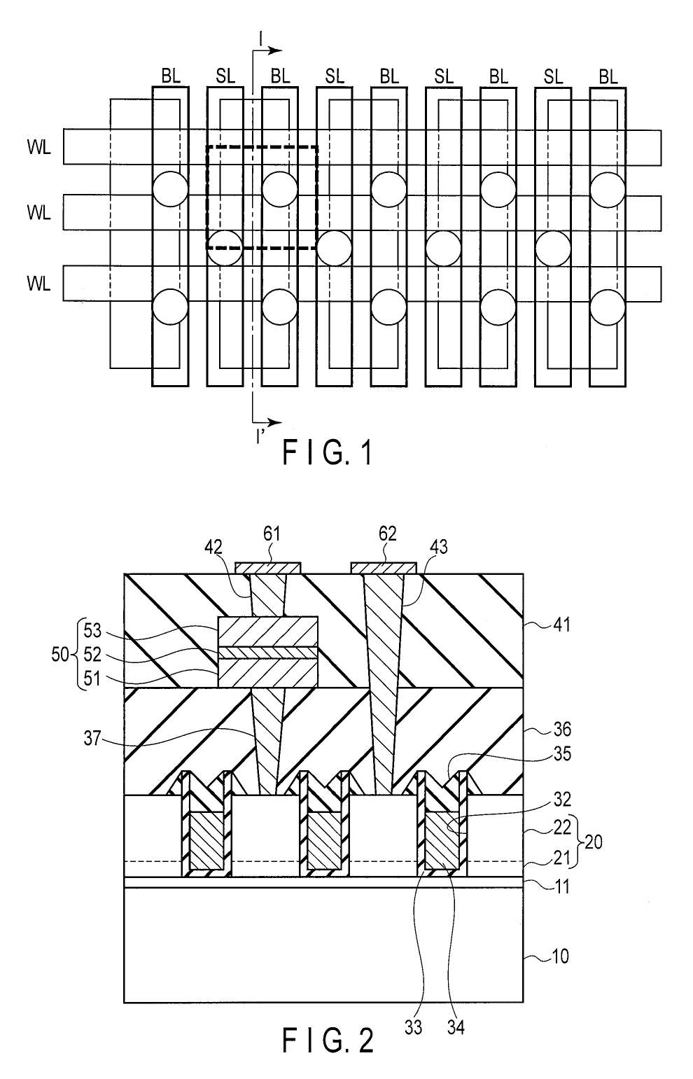

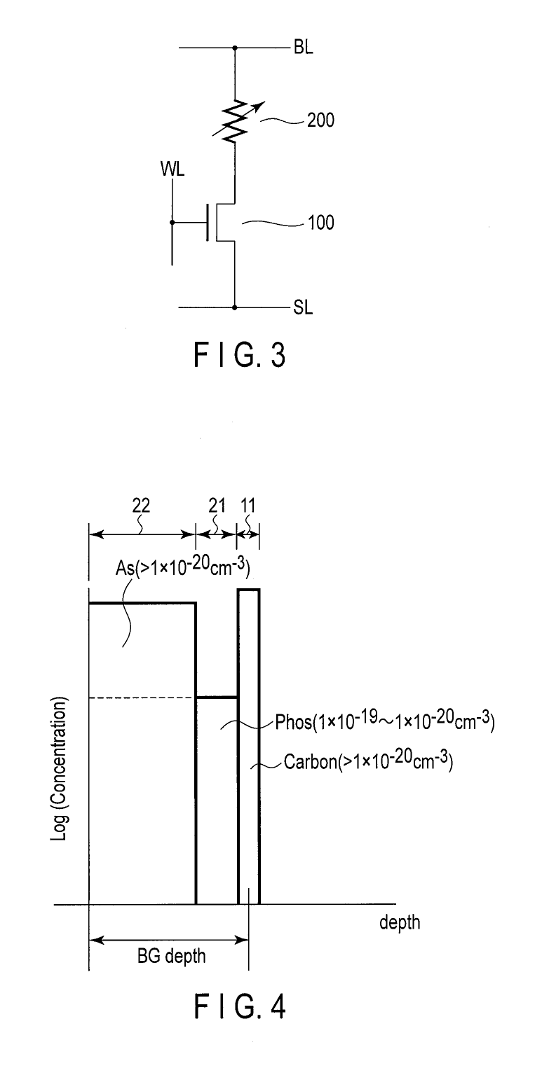

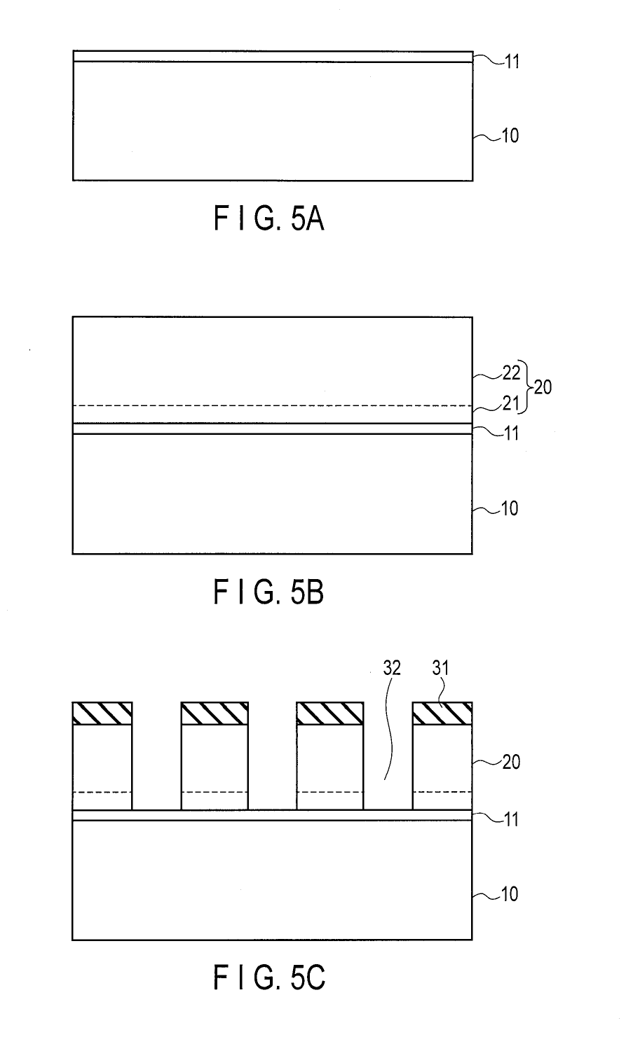

FIGS. 1 to 3 are schematic structure views illustrating a resistance-change memory according to a first embodiment. FIG. 1 is a plan view illustrating an arrangement relationship between a word line WL, a bit line BL, a source line SL and a contact unit. FIG. 2 is a sectional view of FIG. 1 with respect to arrows I-I′, illustrating a memory cell unit. FIG. 3 is a circuit configuration illustrating a cell portion of the resistance-change memory.

As shown in the plan view of FIG. 1, a plurality of word lines WLs that function as a gate electrode are arranged in parallel at predetermined intervals. The source line SL and the bit line BL are alternately arranged at predetermined intervals so as to be orthogonal to the word line WL. The source of a transistor in which the word line WL is a gate electrode is connected to the source line SL in the contact unit. In addition, the drain of the transistor is connected to the bit line BL via a resistance-change element (not shown) in the contact unit.

That is, as shown in FIG. 3, a memory cell, in which a transistor 100 having the word line WL as a gate and a two-terminal resistance-change element 200 are connected in series, is arranged between the source line SL and the bit line BL. The resistance-change element 200 should be an element whose resistance varies by a magnetic field or a current. For the resistance-change element 200, it is possible to constitute a magnetoresistive random access memory (MRAM) by using, for example, a MTJ element in which a tunnel barrier layer is sandwiched by a ferromagnetic layer.

The structure of a transistor unit used for the resistance-change memory of the first embodiment is shown in FIG. 2. A C-doped layer (first semiconductor layer) 11, which is a Si epitaxial layer containing high-concentration carbon, is formed on the surface side of a Si substrate (semiconductor substrate) 10. On the C-doped layer 11, an n-type Si epitaxial layer (second semiconductor layer) 20 is formed. The Si epitaxial layer 20 is formed by a phosphorous-doped (P-doped) layer (first impurity diffusion region) 21 and an arsenic-doped (As-doped) layer (second impurity diffusion region) 22. These doped layers 21 and 22 correspond to an S/D region of the transistor.

On the Si epitaxial layer 20, a groove part 32 configured to form a gate portion of a MOS transistor is formed. In the groove part 32, a gate electrode 34 is embedded and formed in the groove part 32 via a gate insulating film 33. The gate electrode 34 is embedded halfway in the groove part 32. A cap layer (gate protection insulating film) 35 is embedded and formed thereabove. The top face of the cap layer 35 is positioned higher than the substrate surface (the top face of the Si epitaxial layer 20).

Also, an interlayer insulating film 36 is formed on the substrate on which the transistor unit is formed. A contact plug 37 is embedded and formed in the interlayer insulating film 36 so as to be connected to the drain of the transistor unit. An MTJ element 50 is formed on the interlayer insulating film 36. The MTJ element 50 is structured so that a nonmagnetic tunnel barrier layer 52 is sandwiched by a ferromagnetic recording layer 51 whose magnetization direction is variable and a ferromagnetic reference layer 53 whose magnetization direction is fixed. The recording layer 51 is connected to the contact plug 37.

An interlayer insulating film 41 is formed so as to cover the MTJ element 50. A contact plug 42, which is connected to the reference layer 53 of the MTJ element 50, is embedded and formed in the interlayer insulating film 41. Also, a contact plug 43, which is connected to the source of the transistor unit, is embedded and formed by passing through the interlayer insulating film 41 and the interlayer insulating film 36. On the interlayer insulating film 41, an interconnect (BL) 61 connected to the connecter plug 42 and an interconnect (SL) 62 connected to the contact plug 43 are formed.

In a cell transistor of a DRAM and a resistance-change memory, a contact area needs to be enlarged so as to reduce a contact resistance with a source/drain. In the first embodiment, it is possible to reduce the width of a gate electrode sidewall part and the height of a gate electrode (including a gate cap material) from the substrate surface by using an embedded-gate transistor as shown in FIG. 2. The contact area can be thus enlarged as much as possible even when a self-aligned contact is formed. Therefore, it is expected to reduce the contact resistance.

Also, an embedded gate structure has the important feature of being insulated from a contact plug since the upper portion is capped by an insulating film. This leads to an advantage that even if a contact hole is widened in lithography processing, the contact hole can be etched and opened without taking the misalignment into account.

In the assumption of cell layout, the size of a contact radius usually needs to be made extremely small if the size variation and misalignment of lithography are taken into account. However, in an embedded-gate cell transistor, a part of a contact hole is allowed to be on the gate since the upper portion of the gate is insulated by gate capping insulator film. A certain amount of contact area is thereby achieved.

Further, in the first embodiment, a source/drain region of the embedded-gate cell transistor is formed by growing the Si epitaxial layer 20 while doping impurities into the Si substrate 10. Furthermore, the first embodiment has a feature that carbon is doped in the vicinity between the original Si substrate 10 and an epitaxially-grown portion.

It is thereby possible to maintain to a certain size the relationship between the depth of the groove part 32 and the height of the S/D portion for forming a gate, which inflicts no damage on ion implantation in high energy. It is also possible to uniform the impurity distribution in the doped layers 21 and 22 and to steepen the impurity distribution at the boundary between the doped layers 21 and 22 and at the boundary between the p-doped layer 21 and the Si substrate 10.

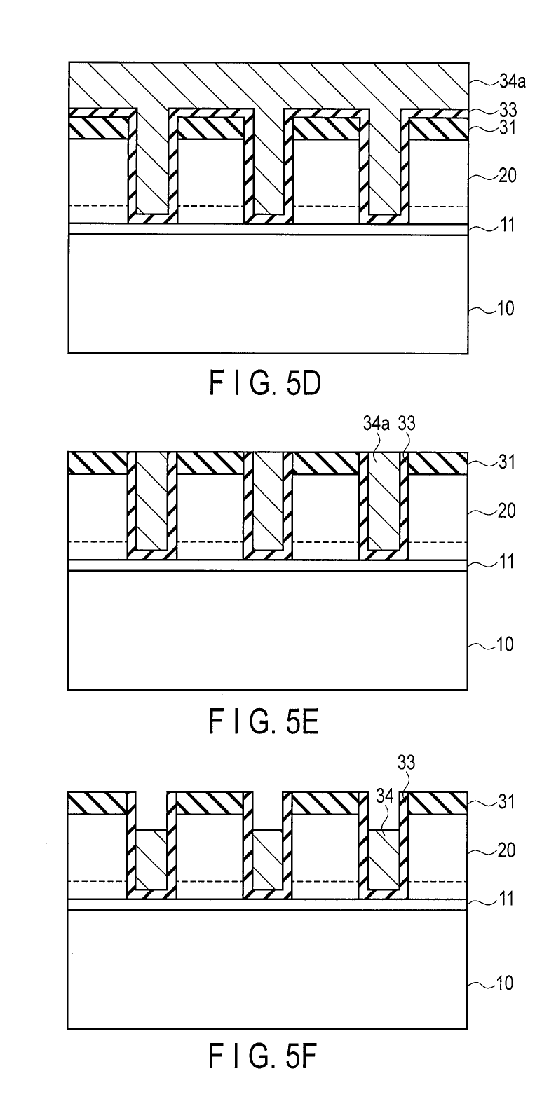

As shown in FIG. 4, after carbon is introduced so that its concentration reaches 1×10²⁰ cm⁻³ or more only in a short time in the beginning of epitaxial growth, phosphorus is epitaxially grown while introduced at a concentration of 1×10¹⁹ to 1×10²⁰ cm⁻³. Also, the epitaxial growth continues while the concentration of arsenic is set to 1×10²⁰ cm⁻³ or more in the middle of the epitaxial growth. It is desired that the concentration of arsenic be 5×10²⁰ cm⁻³ or more.

Under such an impurity concentration profile, while a region equivalent to an S/D extension part in a planar MOSFET is formed by phosphorus on a desired position in a longitudinal direction, high-concentration arsenic exists on the substrate surface. A low-resistance contact region is thereby formed.

Since a so-called BOX impurity of phosphorus and arsenic can be formed on an arbitrary position with each other, it is possible to reduce a spreading resistance and a sheet resistance as compared to when an impurity profile is formed by ion implantation. Therefore, it is possible to improve performance and reduce the short channel effect at the same time.

Also, since the film thickness of the epitaxial growth can be controlled easily, it is possible to control the height of the S/D precisely and to minimize the characteristic variation arising from size variation as compared to forming by conventional etching.

Further, it is possible to make carbon function as a reducer of dopant diffusion for phosphorus and as a stopper/detector for BG etching. The latter can function as an etching stopper by arranging to stop a reactive ion etching (RIE) device upon detection of carbon when BG etching is formed by RIE.

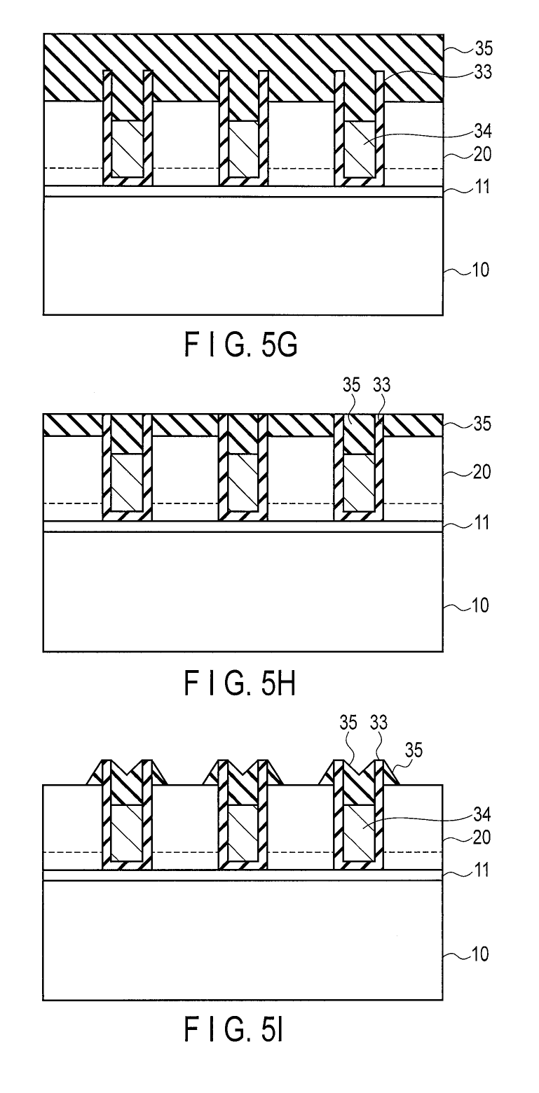

Next, the processes of manufacturing the first embodiment will be explained with reference to FIGS. 5A to 5K.

First, as shown in FIG. 5A, the C-doped layer 11 containing high-concentration carbon is epitaxially grown to a thickness of, for example, 10 nm on the Si substrate (semiconductor substrate) 10. Note that although not shown, the substrate 10 has a memory cell region and a peripheral circuit region, the peripheral circuit region provided with a mask region of SiN or the like to make epitaxial growth selectively only on the memory cell region.

Then, as shown in FIG. 5B, the Si epitaxial layer 20 in which phosphorous or arsenic as n-type impurity are doped is formed. In detail, after the P-doped layer (first impurity diffusion region) 21 is formed by, for example, 10 nm while phosphorus is doped, the As-doped layer (second impurity diffusion region) 22 is formed by, for example, 60 nm while arsenic is doped.

Since carbon reduces dopant diffusion for phosphorus, the existence of the C-doped layer 11 can reduce impurity diffusion from the Si epitaxial layer 20 to the Si substrate 10.

As shown in FIG. 4, the impurity concentrations in the C-doped layer 11, the P-doped layer 21 and the As-doped layer 22 are uniform in a thickness direction, which differs from ion implantation. That is, the impurity concentration distributions in the doped layers 21 and 22 are uniform as being epitaxially grown while impurities are added. This contributes to the improvement of element characteristics. Also, since the impurity concentration of the P-doped layer 21 is lower than that of the doped layer 22, it is possible to form a lightly-doped drain (LDD) structure and an extension layer.

When the phosphorus and arsenic to be added during the growth of the doped layers 21 and 22 are switched, it is possible either to add arsenic while adding a certain amount of phosphorus or to start adding arsenic at the same time of stopping adding phosphorus halfway. In FIG. 4, a continuous line shows a case where addition of phosphorous is stopped halfway while a broken line shows a case where addition of phosphorous is continued. As to the C-doped layer 11, since its film thickness is extremely thin, it may be possible to ion-implant carbon on the surface of the Si substrate 10 right before epitaxial growth. It may also be possible to ion-implant carbon after a non-doped Si epitaxial layer is formed.

In addition, in order to further reduce the resistance of the Si epitaxial layer 20, it may be possible that the surface of the Si epitaxial layer 20 is silicided by depositing Ni, Ti, Co and the like and adding an appropriate heating process.

Subsequently, as shown in FIG. 5C, after depositing on the Si epitaxial layer 20 an insulating film 31 such as SiO₂ that can be a mask material for forming a buried gate (BG) region, the insulating film 31 is patterned to a gate pattern by a known lithography technique. Further, the groove part 32 having a width of approximately 30 nm and a depth of approximately 150 to 200 nm is formed by using the insulating film 31 as a mask and by selectively etching the Si epitaxial layer 20 by RIE until it reaches the C-doped layer 11. As the groove part 32 is used for embedding a gate electrode, the bottom part of the groove part 32 can be a channel region of a transistor while the side part of the groove part 32 can be a source/drain region of a transistor.

By etching while monitoring carbon in the C-doped layer 11, it is possible to determine the depth of the groove part 32 with excellent controllability. Note that over-etching can be performed after detection of carbon to prevent the Si epitaxial layer 20 from remaining.

Then, as shown in FIG. 5D, by an atomic-layer deposition (ALD) method or the like, the gate insulating film 33 having a thickness of 3 nm of HfO₂ or the like is formed as a high-k film on the wall face of the groove part 32. After that, a conductive film that can be a gate electrode material such as a tungsten (W) film 34a is deposited so as to embed the groove part 32, by a metal organic atomic-layer deposition (MOALD) method and a metal organic chemical vapor deposition (MOCVD) method.

Then, as shown in FIG. 5E, the W film 34a is flattened by CMP to eliminate the unnecessary portions of the upper layer. Note that CMP is performed also for the gate insulating film 33 so that the surface of the insulating film 31 is exposed.

Then, as shown in FIG. 5F, the gate material that remains in the BG region is further etched back to form the gate electrode 34 having a desired height. A space in which an insulating film is embedded is thereby formed in the upper part of the groove part 32.

Then, as shown in FIG. 5G, after eliminating the insulating film 31, a cap layer (gate protection insulating layer) 35 containing SiN is deposited as a cap material on the semiconductor layer 20 by a CVD method so as to embed in the groove portion 32.

Then, as shown in FIG. 5H, the surface is flattened by eliminating the unnecessary portions of the deposited cap layer 35 by CMP or the like.

Then, as shown in FIG. 5I, the cap layer 35 is etched back by anisotropic etching so as to remain only on the gate electrode. If HfO₂ is used as the gate insulating film 33 to use anisotropic etching for eliminating SiN, the non-etched gate insulating film 33 remains and a sidewall region made of a cap material is formed around the film.

Then, as shown in FIG. 5J, the surface is flattened by depositing the interlayer insulating film 36 containing SiO₂ by the CVD method.

Then, as shown in FIG. 5K, after forming on the interlayer insulating film 36 a contact hole that reaches the surface of the conductive layer 20, the contact plug 37 is formed by embedding a conductive material in the contact hole. If a gate cap material (the cap layer 35) is configured as shown in FIG. 5K, it is possible to prevent short circuit between the gate and contact even when misalignment occurs in contact forming.

Thereafter, the MTJ element 50 is formed by depositing with sequential sputter or the like the ferromagnetic recording layer 51, which function as a resistance-change element, the nonmagnetic tunnel barrier layer 52 and the ferromagnetic reference layer 53 and by processing them in a necessary pattern. Further, the structure shown in FIG. 2 is completed by forming the interlayer insulating film 41, the contact plugs 42 and 43 and the interconnects 61 and 62.

Thus, according to the first embodiment, since the C-doped layer 11 is formed on the surface of the Si substrate 10 and then the Si epitaxial layer 20 of dopes impurities is grown thereon, it is possible to form a semiconductor layer in good quality without generating crystal defects as compared to forming an impurity diffusion layer by ion implantation. Further, since the thickness of epitaxial growth can be precisely controlled, it is possible to determine the depth of the source/drain region exactly as compared to the conventional ion implant process. Furthermore, there is no possibility that a junction leakage current is increased by a heating process after ion implantation. Therefore, it is possible to realize an element structure that inhibits the generation of crystal defects while reducing the variation in transistor characteristics.

Also, by forming the groove part 32 of an embedded gate after the source/drain region, it is possible to reduce the variation in their sizes (variation in height and depth). Furthermore, by using the C-doped layer 11 as an end point monitor of etching, it is possible to determine the depth of the groove part 32 for embedding a gate with excellent controllability. Therefore, it is possible to stably and precisely control the shape (height) of the source/drain region and that of the gate electrode region of the embedded-gate MOSFET and to form an element having a size that varies to a lesser extent. Accordingly, it is possible to realize a cell transistor having high capability, small leakage current and less characteristic variation.

In addition, there is an advantage of preventing short circuit between the gate and contact since a gate cap material can be arranged by protruding a bit from the groove part 32.

### SECOND EMBODIMENT

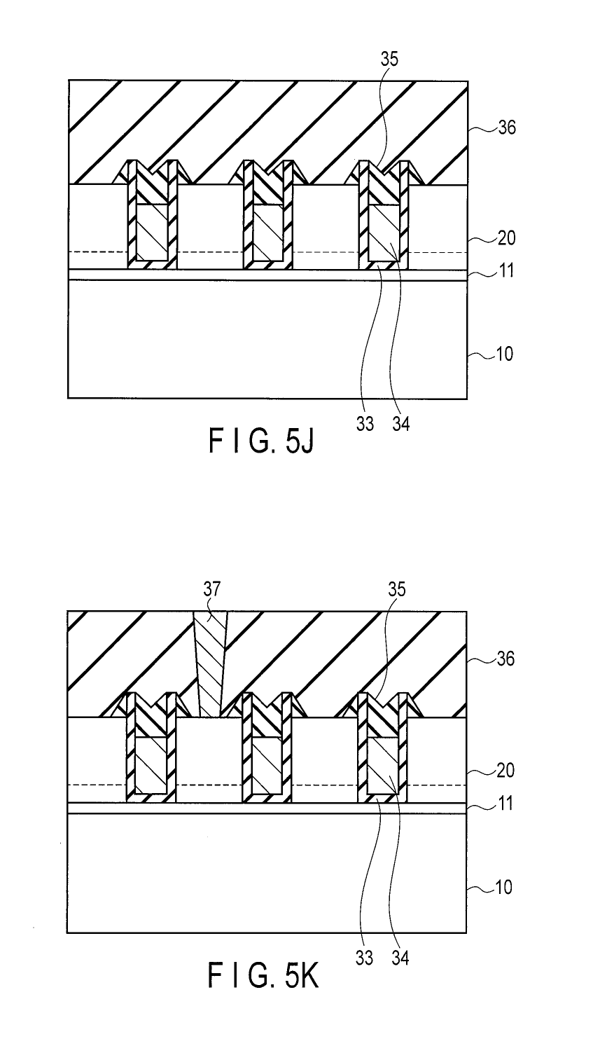

FIG. 6 is a cross-sectional view illustrating a structure of a memory cell unit of a resistance-change memory according to a second embodiment. Note that the same portions as FIG. 2 are given the same reference numerals to omit the detailed explanation.

The second embodiment differs from the first embodiment in that an oxide film and a nitride film are used instead of a high-k film as a gate insulating film 73. The cap layer (gate protection insulating film) 35 is embedded on the gate electrode 34 of the groove part 32. The cap layer 35 is formed only in the groove part 32 without protruding outside the groove part 32.

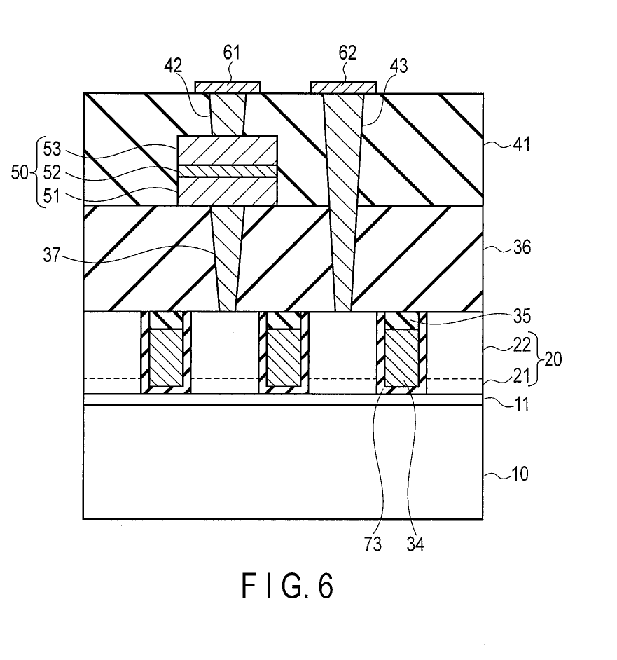

In the second embodiment, in the process shown in FIG. 5D of the first embodiment, the gate insulating film 73 containing SiON is formed by thermal oxidation and plasma nitridation. After the gate electrode 34 is formed in the same way as the first embodiment, the cap layer 35 containing SiN is deposited as a gate cap material so as to embed in the groove part 32 by a CVD method, as shown in FIG. 7A.

Next, as shown in FIG. 7B, the surface is flattened by eliminating the unnecessary portions of the cap layer 35 by CMP.

Subsequently, as shown in FIG. 7C, the cap layer 35 is etched back by anisotropic etching so as to remain only on the gate electrode. At this time, the gate insulating film 73 is also etched since the gate insulating film 73 contains SiOn and has a similar composition to that of the cap layer 35.

Thereafter, the structure shown in FIG. 6 is completed by forming the interlayer insulating film 36, the contact plug 37, the MTJ element 50, the interlayer insulating film 41, the contact plug 43 and the interconnects 61 and 62, in the same way as the first embodiment.

Even under such a structure, it is possible to enlarge an area of an S/D exposed on the substrate surface as well as to obtain the same effect as the first embodiment. This is effective when no short circuit occurs between the gate and contact.

### THIRD EMBODIMENT

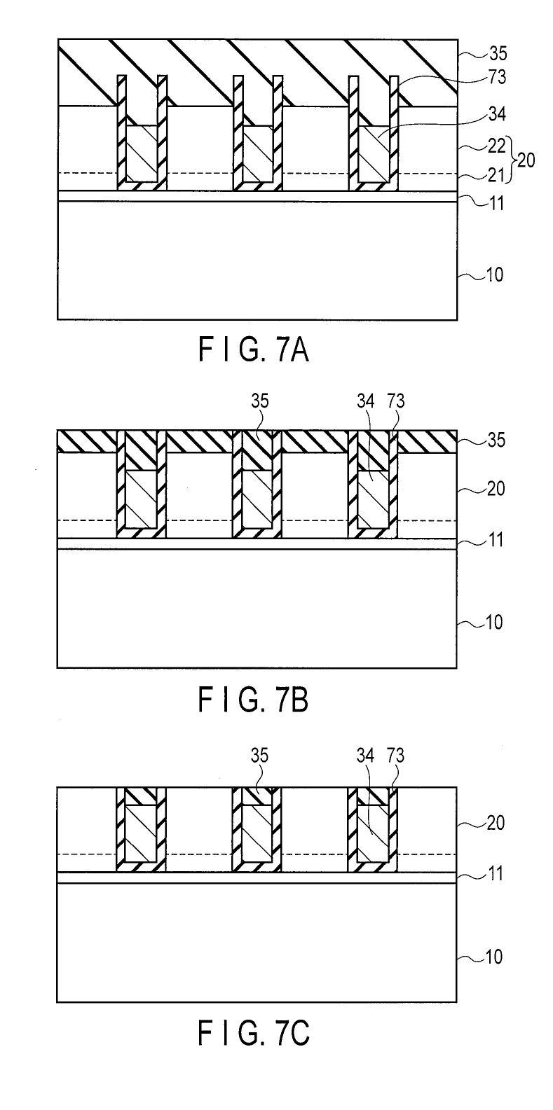

FIG. 8 is a cross-sectional view illustrating a structure of a memory cell unit illustrating a resistance-change memory according to a third embodiment. Note that the same portions as FIG. 2 are given the same reference numerals to omit the detailed explanation.

The third embodiment differs from the first embodiment in that the amount of over-etching performed after detection of carbon in the C-doped layer 11 is increased at the time of forming a groove for forming a gate part.

By increasing the amount of over-etching, the C-doped layer 11 is passed through to partially eliminate the surface part of the substrate 10. The subsequent processes are conducted in the same way as the first embodiment.

Under such a structure, it is possible to prevent the C-doped layer 11 from remaining in the channel as well as to obtain the same effect as the first embodiment. Therefore, it is possible to reduce mobility due to the existence of the C-doped layer 11 and to curb the increase of an S factor due to the increase of interface level density.

### FOURTH EMBODIMENT

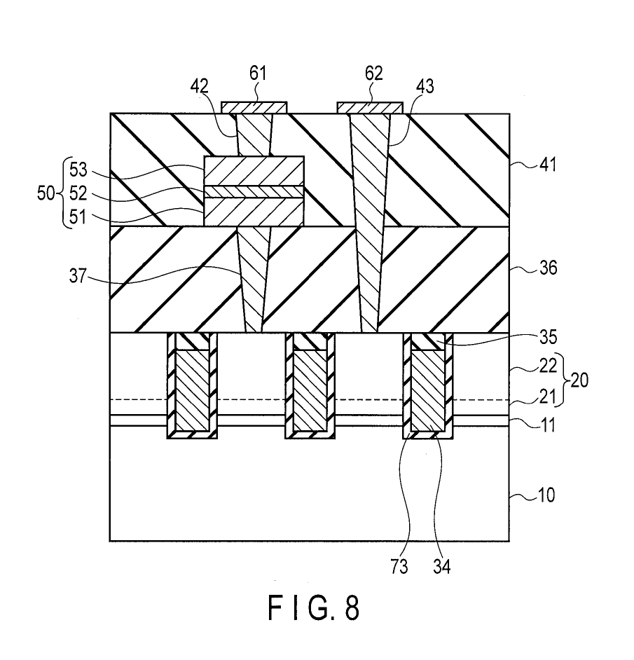

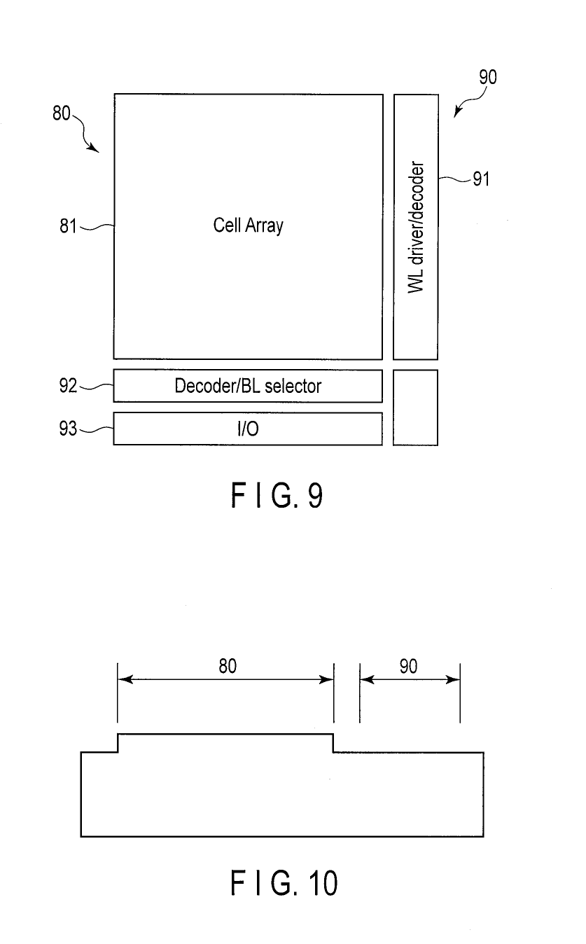

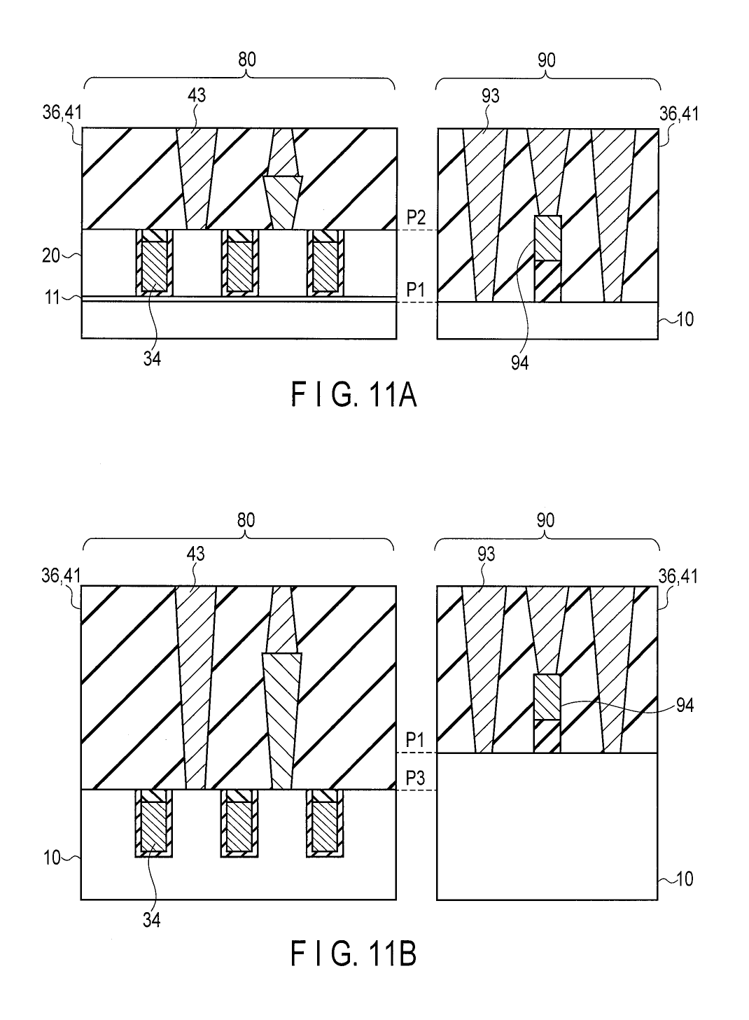

FIG. 9 is a plan view illustrating a schematic structure of a resistance-change memory according to a fourth embodiment. FIG. 10 is a pattern view illustrating a height of a substrate surface in the resistance-change memory of FIG. 9. FIGS. 11A and 11B are cross-sectional views illustrating an effect of the fourth embodiment.

As shown in FIG. 9, it is assumed that a memory cell region 80, in which a cell array 81 is formed, and a periphery circuit region 90, in which each type of decoder 91 and 92, an I/O interface circuit 93 and the like are formed around the memory cell region 80, are arranged in a chip. In this case, as shown in FIG. 10, the memory cell 80 is positioned higher than the periphery circuit region 90. This arises from the difference in a method of manufacturing a transistor of a memory cell unit.

As shown in FIG. 11A, by forming a cell transistor as explained in the first embodiment, the memory cell region 80 grows the Si epitaxial layer 20 from the position of the surface of the Si substrate 10, an uppermost surface P2 of an active region comprising the Si epitaxial layer 20 is positioned higher than a substrate surface P1 of the periphery circuit region 90. Therefore, it is possible to reduce an aspect ratio of a contact of the memory cell unit in a direction of absorbing the height of a gate electrode 94 of a peripheral transistor. Note that 93 in the figure represents a contact plug in the peripheral circuit region 90. Also, while FIG. 11A shows an example of the C-doped layer 11 provided, the C-doped layer 11 can be omitted.

On the other hand, as shown in FIG. 11B, if a cell transistor is formed by embedding the Si substrate 10 from the initial position in the memory cell region 80, a surface P3 of the active region is positioned lower than the substrate surface P1 of the peripheral circuit region 90. In addition, since the peripheral circuit region 90 is provided with a gate electrode of a transistor so as to protrude in an upper direction, the aspect ratio of a contact hole in the memory cell region is increased. Therefore, it is difficult to process the contact hole in the memory cell region 80.

Thus, according to the fourth embodiment, the Si epitaxial 20 formed on the Si substrate 10 by epitaxial growth is treated as a source/drain in an embedded-gate transistor formed in the memory cell region 80. Therefore, even when the surface of the same uppermost interlayer insulating layer is flattened in the memory cell region 80 and the periphery circuit region 90, it is possible to reduce the aspect ratio of the contact in the memory cell region 80. This has the advantage of facilitating manufacture.

### (Example of Deformation)

Note that the present invention is not limited to the above-mentioned embodiments.

While a magnetic resistance effect element such as MTJ is used as a resistance-change element in the embodiments, it is preferable that the resistance be changed by a magnetic field or an electric field.

While a resistance-change memory is taken as an example in the above explanation in the embodiments, it is applicable to a DRAM, not limited thereto. Further, a semiconductor device having an embedded gate electrode as well as a semiconductor having a memory is applicable.

Furthermore, the material of a gate electrode, a gate insulating film and a protection insulating film are not limited to the embodiments; they are appropriately applicable in accordance with a specification.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor substrate;
a first semiconductor layer formed on a main surface of the semiconductor substrate, the first semiconductor layer containing carbon;
a second semiconductor layer formed on the first semiconductor layer, the second semiconductor layer containing impurities;
a groove part arranged so as to pass through the second semiconductor layer; and
a gate electrode embedded in the groove part via a gate insulating film.

2. The device of claim 1, wherein the second semiconductor layer comprises a first impurity diffusion region formed on a side of the semiconductor substrate and a second impurity diffusion region formed on the first impurity diffusion region, the second impurity diffusion region having a higher impurity concentration than the first impurity diffusion region.

3. The device of claim 2, wherein each impurity concentration of the first impurity diffusion region and the second impurity diffusion region is almost uniform in a depth direction.

4. The device of claim 2, wherein an impurity of the first impurity diffusion region is phosphorus (P) and an impurity of the second impurity diffusion region is arsenic (As).

5. The device of claim 1, wherein an upper end of the gate electrode is positioned lower than an upper surface of the second semiconductor layer.

6. The device of claim 1, wherein an upper end of the gate insulating film is positioned higher than the upper surface of the second semiconductor layer.

7. The device of claim 6, wherein a gate protection insulating film is formed so as to cover the gate electrode and the gate insulating film, the gate protection insulating film formed around the gate insulating film.

8. The device of claim 1, wherein the gate electrode is a gate electrode of a transistor for switching, further comprising a two-terminal resistance-change element connected to the transistor above the second semiconductor layer, wherein the transistor and the resistance-change element constitute a memory cell.

9. A nonvolatile semiconductor memory device, comprising:
a semiconductor substrate comprising a memory cell region and a peripheral circuit region;
a semiconductor layer formed on the memory cell region of the semiconductor substrate, the semiconductor layer having impurities diffused;
a groove part provided so as to pass through the semiconductor layer;
a gate electrode embedded in the groove part of the semiconductor layer via a gate insulating film;
an interlayer insulating film formed on the gate electrode and the semiconductor layer; and
a resistance-change element formed on the interlayer insulating film, one of two terminals being electrically connected to a source or a drain of the transistor, wherein
the memory cell region is positioned higher than the peripheral circuit region on a surface of an active region comprising the semiconductor layer.

10. The device of claim 9, further comprising a layer containing carbon between the semiconductor substrate and the semiconductor layer.

11. The device of claim 10, wherein the semiconductor layer comprises a first impurity diffusion region formed on a side of the semiconductor substrate and a second impurity diffusion region formed on the first impurity diffusion region, the second impurity diffusion region having a higher impurity concentration than the first impurity diffusion region.

12. The device of claim 11, wherein each impurity concentration of the first impurity diffusion region and the second impurity diffusion region is almost uniform in a depth direction.

13. The device of claim 11, wherein an impurity of the first impurity diffusion region is P and an impurity of the second impurity diffusion region is As.

14. The device of claim 9, wherein the resistance-change element is formed by sandwiching a tunnel barrier layer comprising a nonmagnetic body by a recording layer comprising a ferromagnetic body whose magnetization direction is variable and a reference layer comprising a ferromagnetic body whose magnetization direction is fixed.

15. A method of manufacturing a semiconductor device, comprising:
forming a first semiconductor layer containing carbon on a main surface of a semiconductor substrate;
epitaxially-growing on the first semiconductor layer a second semiconductor where impurities are doped;
forming a groove part reaching the first semiconductor layer by selectively etching the second semiconductor layer; and
embedding a gate electrode in the groove part via a gate insulating film.

16. The method of claim 15, wherein the forming the groove part is configured to selectively etch the second semiconductor layer by RIE and uses the carbon of the first semiconductor layer as an end point monitor.

17. The method of claim 15, wherein the forming the second semiconductor layer is configured to form a first impurity diffusion region on the semiconductor substrate and then forms on the first impurity diffusion region a second impurity diffusion region having a higher impurity concentration than the first impurity diffusion region.

18. The method of claim 17, wherein P is used as an impurity of the first impurity diffusion region and As is used as an impurity of the second impurity diffusion region.

19. The method of claim 15, wherein after the gate electrode is formed, an interlayer insulating layer is formed on the second conductor layer and the gate electrode and a resistance-change element in which one of two terminals is electrically connected to a source or a drain of the transistor is formed on the interlayer insulating film.
